(19) United States
(12) Patent Application Publication
(10) Pub. No.: US 2004/0174680 A1
(43) Pub. Date: Sep. 9, 2004

(54) Circuit arrangement for components to be cooled and corresponding cooling method

(75) Inventors: Martin Grabner, Dietramszell (DE); Friedrich Witzani, Munchen (DE)

Correspondence Address: OSRAM SYLVANIA INC, 100 ENDICOTT STREET, DANVERS, MA, 01923, US

(73) Assignee: PATENT-TREUHAND-GESELLSCHAFT FUR ELEKTRISCHE GLUHL, MUNCHEN (DE)

(21) Appl. No.: 10/782,775

(22) Filed: Feb. 23, 2004

(30) Foreign Application Priority Data
Mar. 7, 2003 (DE) 103 10 141.1

(51) Int. Cl. H05K 7/20

(52) U.S. Cl. 361/704

(57) ABSTRACT

The invention proposes a simpler way of removing heat from integrated power components. For this purpose, a heat transfer device, in particular a thermally conducting mat (3), is inserted between the components (2) to be cooled and a core of an inductive component (4). The heat produced by the power semiconductors (2) can thus be dissipated to the core of the inductive component (4).

### FIELD OF THE INVENTION

The present invention relates to a circuit arrangement having an electronic component to be cooled and an inductive component which has a core. Furthermore, the present invention relates to a corresponding method for cooling an electronic component.

### BACKGROUND OF THE INVENTION

Integrated circuits often have such a high power consumption that they need to be cooled. Suitable cooling means are usually provided for this purpose. Such cooling means comprise, for example, cooling plates or cooling bodies which are relatively bulky. When a very large amount of heat is dissipated, the electronic components may also be actively cooled by means of a fan. In any case, sufficient cooling is only ensured when the cooling means can absorb sufficient energy. This generally means that the cooling means needs to have a relatively large surface area in order for it to be possible for the absorbed heat also to be dissipated again to a sufficient extent.

In many applications, however, the circuit arrangements should be as compact as possible owing to the small amount of space which is available. The cooling bodies should therefore also be kept as small as possible.

### SUMMARY OF THE INVENTION

It is therefore the object of the present invention to propose a circuit arrangement in which the components can be cooled sufficiently well even when there is only a small amount of space available. The invention also proposes a corresponding cooling method.

This object is achieved according to the invention by a circuit arrangement having a component to be cooled, an electrical component in the form of a heat sink, which is an active part of the circuit arrangement, in particular an inductive component having a core, and a heat transfer device, which is arranged between the component to be cooled and the electrical component in the form of a heat sink such that it is in direct contact with the two for the purpose of removing heat from the component to be cooled.

According to the invention, a method is also provided for cooling an electronic component of an electrical circuit by providing the component to be cooled of the electrical circuit, providing an electrical component, actively participating in the electrical circuit in the form of a heat sink, in particular an inductive component having a core, and inserting a heat transfer device between the component to be cooled and the component acting as the heat sink such that it is in direct contact with the two for the purpose of removing heat from the component to be cooled.

In this manner, the core of an inductor, which has a relatively large thermal capacitance, can be used as a cooling body or compensating body. There is therefore no need for a specially provided cooling body, and a circuit arrangement can be of more compact design.

The heat transfer device is preferably produced in the form of a mat from a resilient material. The contact surface between the mat, on the one hand, and the component to be cooled or the core, on the other hand, can thus be ensured when the component is pressed against the core. Such a resilient mat may be produced from a foamed mass.

The inductive component may comprise a transformer. The core of the transformer generally has a large mass and thus also has a correspondingly high thermal capacitance in order for it to act as a heat sink.

The component to be cooled may be an integrated circuit and, in particular, a power component. Its flat structure facilitates the transfer of heat to the thermal mat.

The circuit arrangement may have two or more components to be cooled, the mat being arranged jointly thereover. This makes it possible to cool two or more components at the same time.

### BRIEF DESCRIPTION OF THE DRAWINGS

The present invention is now explained in more detail with reference to the attached drawings, in which:

FIG. 1 shows a plan view of power semiconductors, which are soldered onto a printed circuit board;

FIG. 2 shows a plan view of the mat according to the invention, under which the power semiconductors of FIG. 1 are arranged;

FIG. 3 shows a perspective view of the arrangement of FIG. 2;

FIG. 4 shows a side view of the arrangement of FIG. 2 with a transformer fitted on top; and

FIG. 5 shows an end face view of the arrangement of FIG. 4.

### DETAILED DESCRIPTION OF THE INVENTION

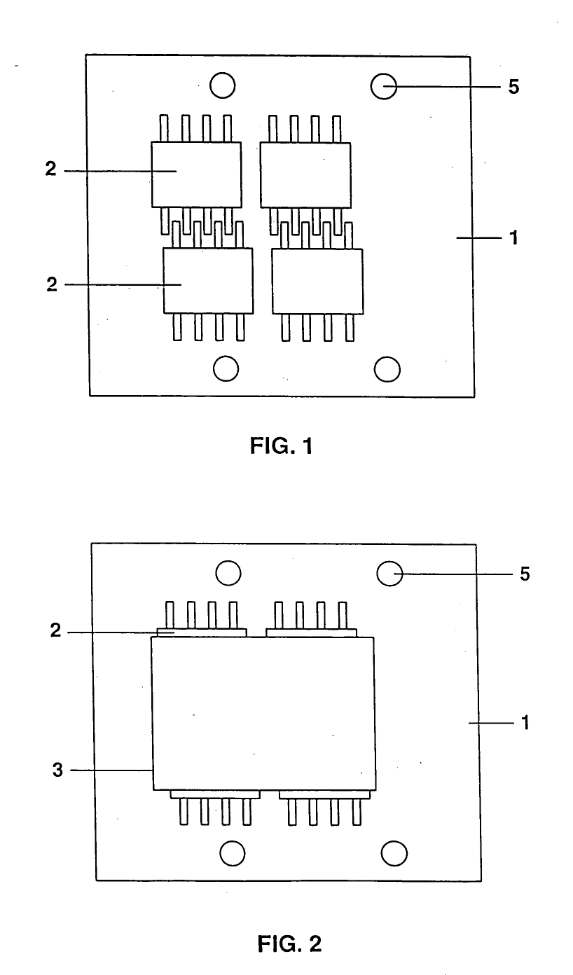

The exemplary embodiment described in more detail below is a preferred embodiment of the present invention. Two or more integrated circuits having power semiconductors 2 (power semiconductors for short) are soldered, in the direct vicinity of one another, onto a printed circuit board 1, as is shown in the plan view of FIG. 1. The power semiconductors 2 have an energy consumption which requires special cooling measures.

The four power semiconductors 2 are in the present case integrated in so-called SO8 housings. Each of these housings has a flat surface which each lie together in one plane. A thermally conductive mat 3 may therefore easily be placed on the power semiconductors 2, as shown in FIG. 2.

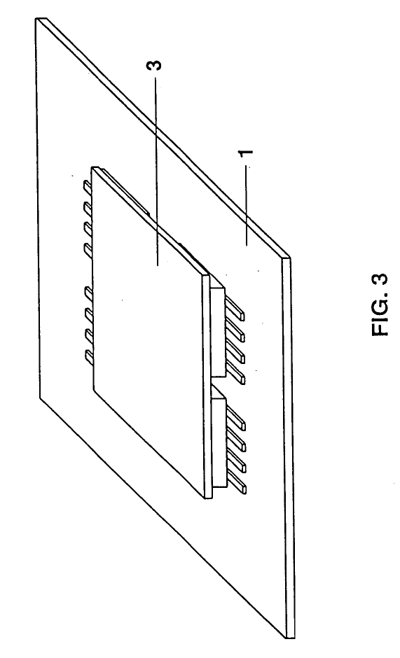

FIG. 3 shows a perspective view of this. The thermally conductive mat 3, which is made of a foamed, electrically insulating material, covers all of the integrated circuits 2 to be cooled. The mat 3 may have a special coating on its surface for reasons of stability or of heat transfer.

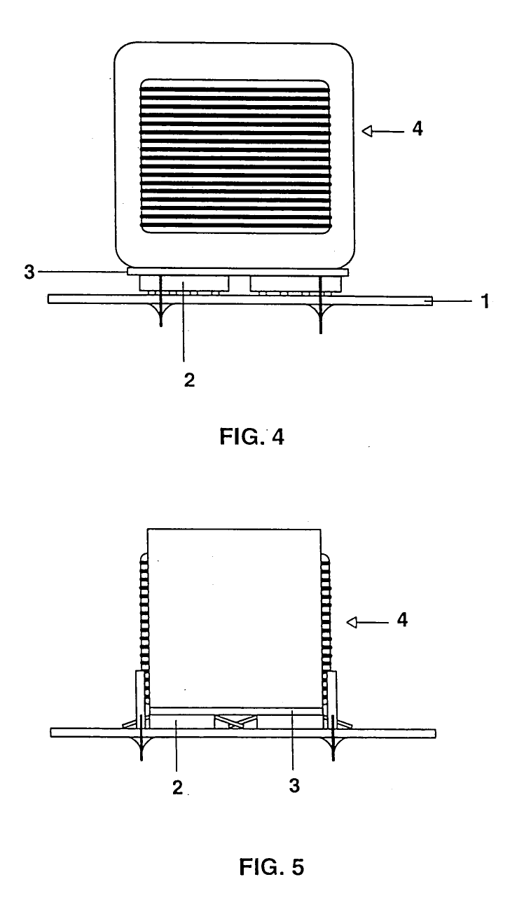

FIG. 4 now shows a transformer which is pressed onto the power semiconductors 2 with the mat 3 lying on top. The transformer 4 is fixed in the holes 5 (see FIG. 1) of the printed circuit board 1 by soldering such that it makes contact with them.

The ferrite core of the transformer 4 therefore presses on the mat 3 and the power semiconductors 2 lying underneath, such that an improved transfer of heat is ensured between the power semiconductors 2 and the ferrite core.

FIG. 5 shows this assembled arrangement once again, in an end face view. It can once again be seen in this view that the mat 3 has a special coating on its surface. It can also be seen that this cooling arrangement makes it possible to achieve a very compact construction, in which there is no need for an additional cooling body, since the ferrite core of the transformer 4 takes on the cooling function.

In an alternative construction, instead of the thermally conductive mat 3, a plastic material may be sprayed between the core of the transformer 4 and the power semiconductors 2 in the form of a heat transfer device. This would have the further advantage that an even larger area of the power semiconductors would be surrounded by the thermally conductive material.

1. A circuit arrangement having
a component (2) to be cooled,
comprising
an electrical component in the form of a heat sink, which is an active part of the circuit arrangement, in particular an inductive component (4) having a core, and
a heat transfer device (3), which is arranged between the component (2) to be cooled and the electrical component in the form of a heat sink such that it is in direct contact with the two for the purpose of removing heat from the component (2) to be cooled.

2. The circuit arrangement as claimed in claim 1, in which the heat transfer device (3) comprises a resilient mat.

3. The circuit arrangement as claimed in claim 2, in which the mat is produced from a foamed mass.

4. The circuit arrangement as claimed in claim 1, in which the inductive component (4) is a transformer.

5. The circuit arrangement as claimed in claim 1, in which the component (2) to be cooled is an integrated circuit.

6. The circuit arrangement as claimed in claim 4, in which the component (2) to be cooled is an integrated circuit.

7. The circuit arrangement as claimed in claim 1, which has two or more components (2) to be cooled, the heat transfer device (3) being arranged jointly thereover.

8. A method for cooling an electronic component (2) of an electrical circuit by
providing the component (2) to be cooled of the electrical circuit,
providing an electrical component, actively participating in the electrical circuit, in the form of a heat sink, in particular an inductive component (4), which has a core, and
inserting a heat transfer device (3) between the component (2) to be cooled and the component acting as the heat sink such that it is in direct contact with the two for the purpose of removing heat from the component (2) to be cooled.

9. The method as claimed in claim 8, in which the heat transfer device (3) comprises a resilient mat.

10. The method as claimed in claim 9, in which the mat is produced from a foamed mass.

11. The method as claimed in claim 8, in which the inductive component (4) is a transformer.

12. The method as claimed in claim 8, in which the component (2) to be cooled is an integrated circuit.

13. The method as claimed in claim 11, in which the component (2) to be cooled is an integrated circuit.

14. The method as claimed in claim 8, in which two or more components (2) to be cooled are provided, which are cooled jointly with the aid of the heat transfer device (3) on the component acting as the heat sink.
